(19) United States
(12) Patent Application Publication
(10) Pub. No.: US 2024/0243723 A1
(43) Pub. Date: Jul. 18, 2024

(54) Bulk Acoustic Wave Resonator with Improved Lateral Wave Suppression

(71) Applicant: Global Communication Semiconductors, LLC, Torrance, CA (US)

(72) Inventors: Romain Gerbe, Torrance, CA (US); Liping D. Hou, Torrance, CA (US); Shing-Kuo Wang, Torrance, CA (US); Yuefei Yang, Torrance, CA (US); Kun-Mao Pan, Harbor City, CA (US); Andy Chien-Hsiang Chen, Cypress, CA (US)

(21) Appl. No.: 18/415,521

(22) Filed: Jan. 17, 2024

Related U.S. Application Data
(60) Provisional application No. 63/439,549, filed on Jan. 17, 2023.

(51) Int. Cl. H03H 9/17; H03H 9/02

(52) U.S. Cl. CPC H03H 9/173; H03H 9/02086; H03H 9/175

(57) ABSTRACT

A bulk acoustic resonator includes a stack structures, including a piezoelectric layer having a first side and an opposing second side; a first electrode disposed under the first side of the piezoelectric layer; a second electrode disposed over the second side of the piezoelectric layer; and a multistep structure with a bottom part having first dimensions disposed between the piezoelectric layer and second electrode and a second part having second dimensions, different from the first dimensions, disposed between the bottom part of the multistep structure and the second electrode. An active region of the stack is configured to resonate in response to an electrical signal applied between the first electrode and the second electrode, and the multistep structure is arranged to provide destructive interference of lateral acoustic waves within the bulk acoustic resonator.

### RELATED APPLICATIONS

This application claims priority to U.S. Provisional Patent Application No. 63/439,549, filed Jan. 17, 2023, which is hereby incorporated by reference in its entirety.

U.S. patent application Ser. No. 17/680,231, filed Feb. 24, 2022, is hereby incorporated by reference in its entirety, and is hereinafter referred to as “background information incorporated by reference into this application.”

### TECHNICAL FIELD

The disclosed embodiments relate generally to bulk acoustic wave resonators, and in particular, to improved bulk acoustic resonators with additional structures that provide destructive interference of lateral acoustic waves.

### BACKGROUND

Bulk acoustic wave (BAW) resonators, also called BAW devices or BAW filters, are widely used as radio frequency (RF) filters in mobile devices due to their compact size and high performance. A BAW resonator typically includes a piezoelectric thin film layer between a bottom electrode and a top electrode. When an oscillating electrical signal is applied between the top and bottom electrodes, the piezoelectric thin film layer converts the oscillating electrical signal into bulk acoustic waves. The resonance frequency of the BAW resonator is mainly determined by the acoustic velocity, the thickness of the piezoelectric layer and those of the electrodes. Piezoelectric thin film materials used for BAW devices include ScAlN, AlN, ZnO, and PZT. In high performance BAW filters, a high quality factor (Q factor) is generally desirable. The performance of BAW resonators depends on the quality of the piezoelectric films therein, but is negatively impacted by lateral acoustic waves, the presence of which decrease the quality factor of BAW resonators.

### SUMMARY

The quality factor of a bulk acoustic wave (BAW) resonator can be improved through the addition of supplemental structures, above or below the piezoelectric layer of the BAW resonator, that are arranged to provide destructive interference of lateral acoustic waves. Providing two or more such supplemental structures, with different lateral dimensions or extents, helps to provide a high quality factor across a relatively broad range of frequencies.

According to a first set of embodiments, a bulk acoustic resonator includes a stack of layers or structures, typically supported by a substrate. The stack includes a piezoelectric layer having a first side and an opposing second side; a first electrode (sometimes called the bottom electrode) disposed under the first side of the piezoelectric layer; a second electrode (sometimes call the top electrode) disposed over the second side of the piezoelectric layer; and a multistep structure with a bottom part (sometimes called a first frame layer) having first dimensions disposed between the piezoelectric layer and second electrode and a second part (sometimes called a second frame layer) having second dimensions, different from the first dimensions, disposed between the bottom part of the multistep structure and the second electrode. An active region of the stack is configured to resonate in response to an electrical signal applied between the first electrode and the second electrode, and the multistep structure is arranged to provide destructive interference of lateral acoustic waves within the bulk acoustic resonator.

In some of the first set of embodiments, the bottom part of the multistep structure has a different thickness (e.g., smaller thickness) than the second part of the multistep structure. In some of the first set of embodiments, the bottom part of the multistep structure is wider (e.g., has a larger lateral extent) than the second part of the multistep structure. In some of the first set of embodiments, the bottom part and the second part of the multistep structure are in contact with each other and the bottom part is in contact with the piezoelectric layer. In some of the first set of embodiments, the bottom part and/or the second part of the multistep structure have sloped edges, with a first side of a respective part having a larger lateral extent than a second side of the respective part.

In some of the first set of embodiments, the multistep structure is comprised of materials that include one or more of titanium, molybdenum, gold, tungsten, ruthenium, silicon, polysilicon, silicon oxide and silicon nitride. In some of the first set of embodiments, the bulk acoustic resonator includes a substrate, and a cavity (e.g., in the substrate) or mirror structure disposed under the stack. In some of the first set of embodiments, the multistep structure includes two or more frame layers, each of which is formed during manufacture of the bulk acoustic resonator by depositing or removing material.

According to a second set of embodiments, a bulk acoustic resonator includes a stack of layers or structures, typically supported by a substrate. The stack includes a piezoelectric layer having a first side and an opposing second side; a first electrode (sometimes called the bottom electrode) disposed under the first side of the piezoelectric layer; a second electrode (sometimes call the top electrode) disposed over the second side of the piezoelectric layer; a first frame layer having first dimensions disposed between the first electrode and the piezoelectric layer or disposed under underneath the first electrode, distal the piezoelectric layer; and a second frame layer having second dimensions, different from the first dimensions, disposed over the second electrode or between the piezoelectric layer and the second electrode. In the second set of embodiments, the first frame layer and second frame layer are disposed on opposite sides of the piezoelectric layer, an active region of the stack is configured to resonate in response to an electrical signal applied between the first electrode and the second electrode, and the first frame layer and the second frame layer are arranged to provide destructive interference of lateral acoustic waves.

In some of the second set of embodiments, the second frame layer is thicker than the first frame layer. More generally, in some of the second set of embodiments, the thickness of the second frame layer is equal to or different from the thickness of the first frame layer. In some of the second set of embodiments, the first frame layer has a larger lateral extent than the second frame layer. In some of the second set of embodiments, the first frame layer includes a first side that is in contact with the first electrode and a second side that is in contact with the piezoelectric layer, and the second frame layer includes a first side that is in contact with the second electrode.

In some of the second set of embodiments, the first frame layer 201 and/or the second frame 202 layer has sloped edges, with a first side of a respective frame layer having a larger lateral extent than a second side (e.g., a side distal the first side) of the respective frame layer.

In some of the second set of embodiments, the first frame layer and second frame layer are comprised of materials that include one or more of titanium, molybdenum, gold, tungsten, ruthenium, silicon, polysilicon, silicon oxide and silicon nitride. In some of the second set of embodiments, the first frame layer and the first electrode, or a portion of the first electrode in contact with the first frame layer, comprise a same material. In some of the second set of embodiments, the first frame layer is integrated in the first electrode. In some of the second set of embodiments, the first electrode comprises a first material, and the first frame layer is formed during manufacture by depositing an additional layer of the first material on top or underneath the first electrode, or by partially removing material of the first electrode.

In some of the second set of embodiments, the bulk acoustic resonator includes a substrate, and a cavity (e.g., in the substrate) or mirror structure disposed under the stack. In some of the second set of embodiments, the stack includes two or more frame layers, each of which is formed during manufacture of the bulk acoustic resonator by depositing or removing material.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

FIGS. 1A1 and 1A2 are cross-sectional diagrams of bulk acoustic wave resonators, in accordance with a first set of embodiments.

FIGS. 1B-1D are cross-sectional diagrams of specific portions of a bulk acoustic wave resonator, in accordance with some embodiments.

FIGS. 2A-2C are cross-sectional diagrams of bulk acoustic wave resonators, in accordance with a second set of embodiments.

FIG. 3 is prophetic diagram, comparing simulated performance of a bulk acoustic wave resonator in accordance with the first set of embodiments with simulated performance of a hypothetical bulk acoustic wave resonator that does not include the multistep structure of the first set of embodiments.

FIG. 4 is prophetic diagram, comparing simulated performance of a bulk acoustic wave resonator in accordance with the second set of embodiments with simulated performance of a hypothetical bulk acoustic wave resonator that does not include the first and second frame layers of the second set of embodiments.

In accordance with common practice the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The various embodiments described herein include systems, methods and/or devices with structures for improved performance and manufacturability.

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

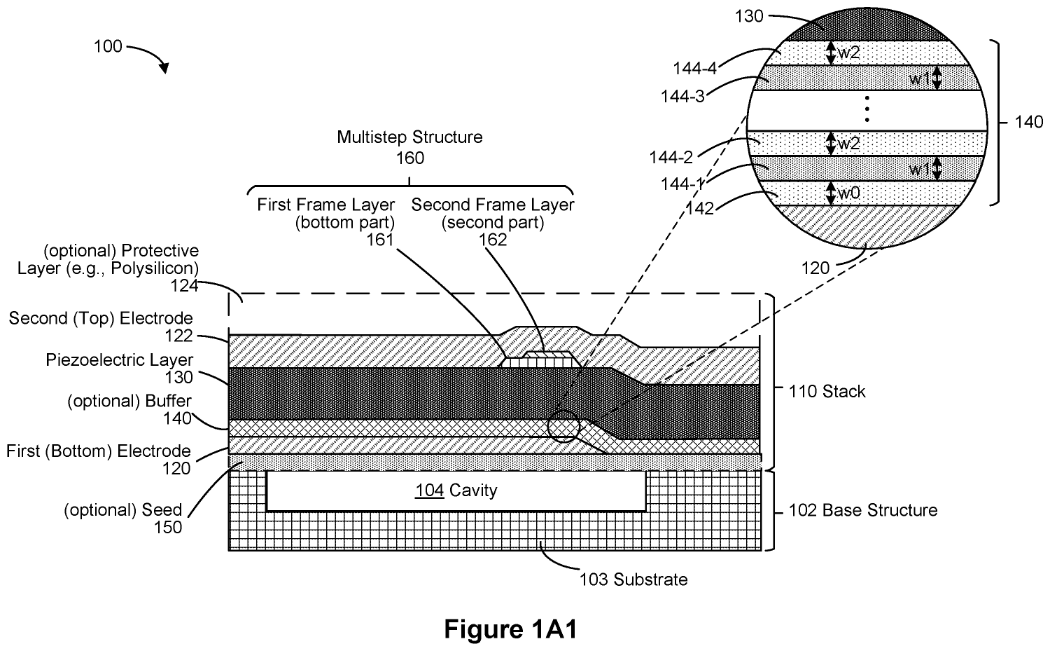

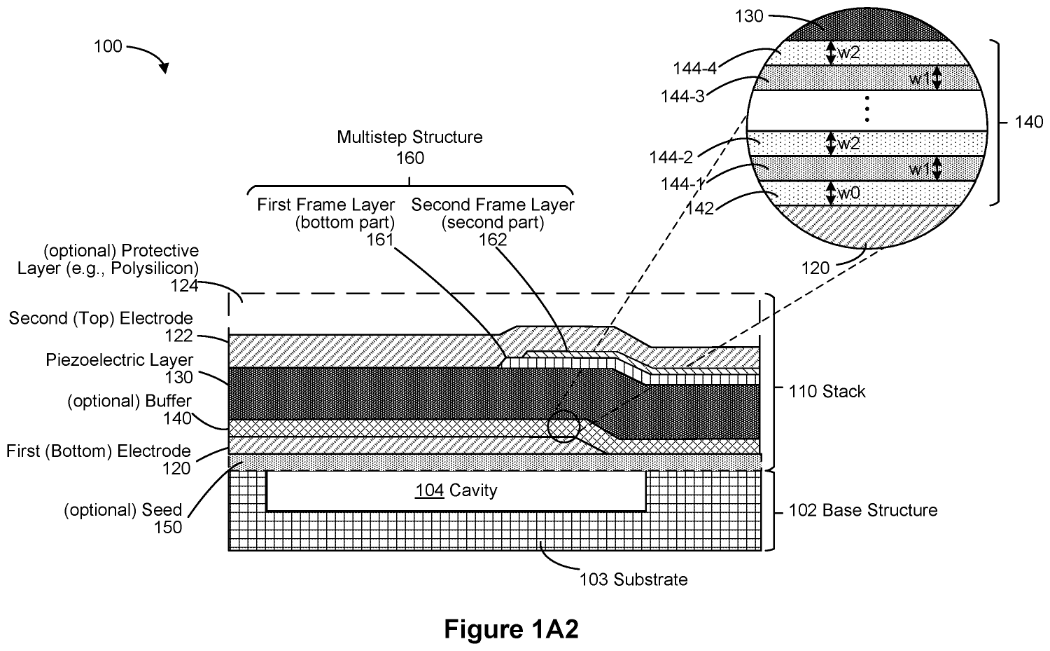

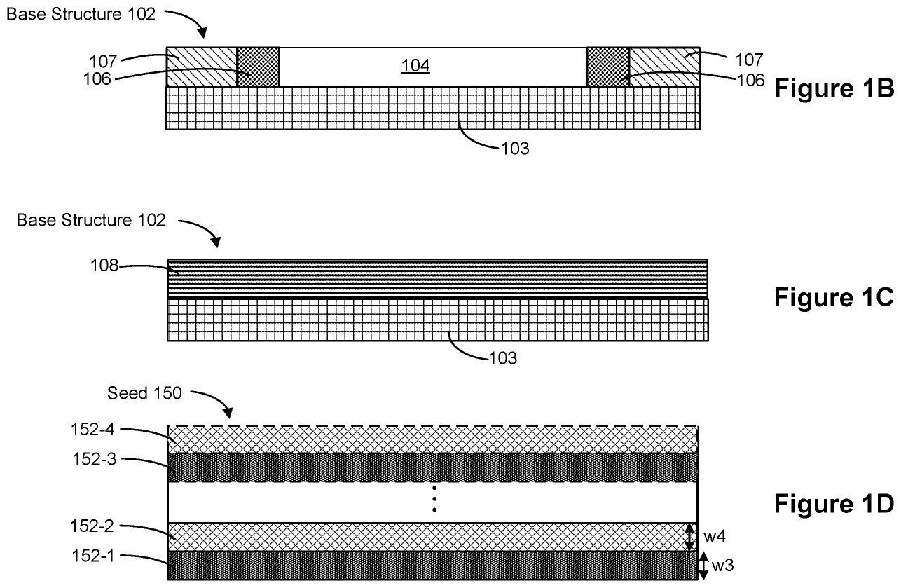

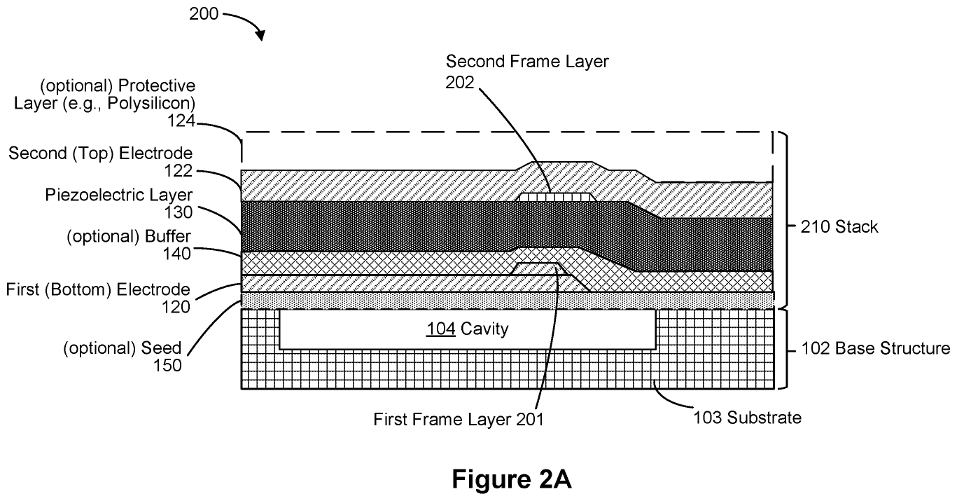

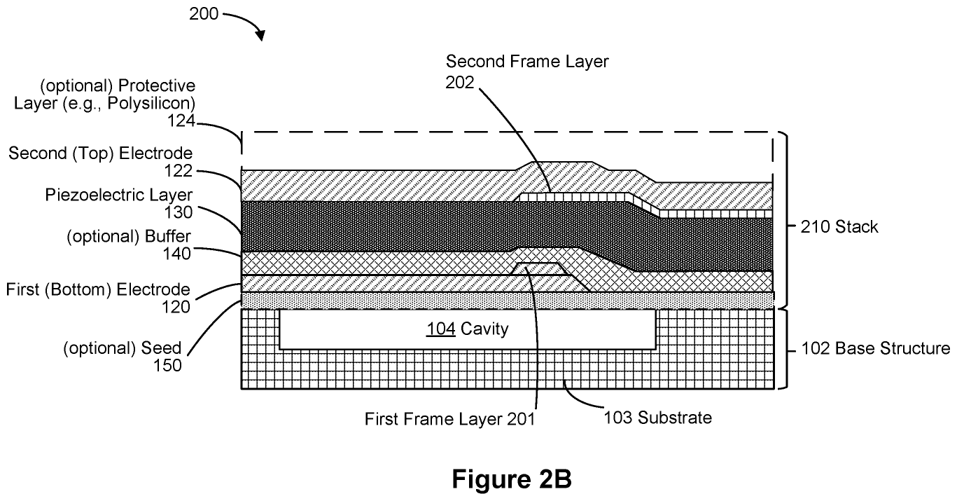

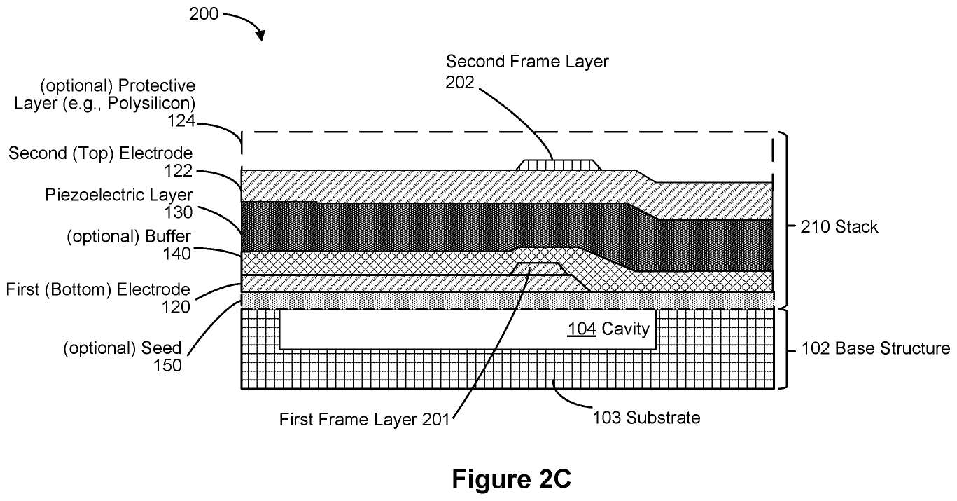

FIGS. 1A1-1A2 are cross-sectional diagrams of bulk acoustic wave (BAW) resonators 100, in accordance with a first set of embodiments. A second set of embodiments are described below with reference to FIGS. 2A-2C.

The BAW resonator 100 shown in FIG. 1A1 includes a base structure 102 (e.g., substrate 103 (e.g., silicon, glass, sapphire, ceramic, gallium arsenide and/or silicon carbide), and a cavity 104), and a stack 110 that is disposed over the base structure 102 (e.g., substrate 103 and the cavity 104). The stack 110 includes a first electrode 120 (e.g., molybdenum, aluminum, and/or tungsten), sometimes called the bottom electrode, a piezoelectric layer 130 (e.g., aluminum nitride, zinc oxide, scandium aluminum nitride, and/or lead zirconate titanate), a second electrode 122 (e.g., molybdenum, aluminum, and/or tungsten), sometimes called the top electrode, and a multistep structure 160 to reduce lateral acoustic waves. The multistep structure 160 is discussed in more detail below.

The stack 110 optionally includes a protective layer 124, e.g., polysilicon, disposed over the second electrode 122. In some embodiments, conductive interconnects (not shown) to the BAW resonator make contact with the second electrode 122 and first electrode 120 through vias in the protective layer 124.

The stack 110 optionally includes a multilayer buffer 140, disposed over the first electrode 120 and between the first electrode 120 and the piezoelectric layer 130. In embodiments that include multilayer buffer 140, discussed in more detail below, piezoelectric layer 130 is disposed over the multilayer buffer 140 and between the multilayer buffer 140 and the second electrode 122.

The stack 110 optionally includes a seed buffer 150, described in more detail below.

### Multistep Structure

In some embodiments, the stack 110 includes a multistep structure 160 that includes a bottom part 161 (sometimes called a first frame layer) having first dimensions disposed between the piezoelectric layer 130 and second electrode 122 and a second part 162 (sometimes called a second frame layer) having second dimensions, different from the first dimensions, disposed between the bottom part 161 of the multistep structure 160 and the second electrode 122. An active region of the stack is configured to resonate in response to an electrical signal applied between the first electrode and the second electrode, and the multistep structure 160 is arranged to provide destructive interference of lateral acoustic waves within the bulk acoustic resonator.

In some of the first set of embodiments, the bottom part 161 of the multistep structure 160 has a different thickness (e.g., smaller thickness) than the second part 162 of the multistep structure 160. For example, the bottom part 161 may have a thickness (e.g., height) between 100 angstroms (100 Å) and 2000 angstroms (2000 Å), while the second part 162 has a thickness (e.g., height) between 200 angstroms (200 Å) and 4000 angstroms (4000 Å). However, in some embodiments, the second part 162 has the same or substantially the same thickness as the first part 161, within a predefined margin of error, for example, a margin of error of twenty percent, or ten percent. For example, the bottom part 161 has a thickness (e.g., height) between 100 angstroms (100 Å) and 4000 angstroms (4000 Å), while the second part 162 has a thickness (e.g., height) between 100 angstroms (100 Å) and 4000 angstroms (4000 Å).

In some of the first set of embodiments, the bottom part 161 of the multistep structure 160 has a larger lateral extent (e.g., is wider) than the second part 162 of the multistep structure 160. For example, the bottom part 161 may have a width between 0.5 microns (0.5 μm) and 6 microns (6 μm), while the second part 162 has a width between 0.3 microns and 5 microns. The bottom part 161 and second part 162 having different lateral extents is important for providing destructive interference of lateral acoustic waves. In some of the first set of embodiments, the multistep structure 160 includes three distinct parts or frame layers, with two or three of the parts or frame layers having a different lateral extent that the other parts or frame layers of the multistep structure 160.

In some of the first set of embodiments, the bottom part 161 and the second part 162 of the multistep structure 160 are in contact with each other and the bottom part 161 is in contact with the piezoelectric layer 130. Stated another way, in such embodiments, the bottom part 161 of the multistep structure 160 includes a first side that is in contact with the piezoelectric layer 130, and the second part 162 of the multistep structure 160 includes a first side that is in contact with a second side of the bottom part 161 of the multistep structure 160. Optionally, in some such embodiments, the first side of the bottom part 161 of the multistep structure 160 has a larger lateral extent (e.g., is wider) than the second side of the bottom part 161 of the multistep structure 162, and thus the edges of the bottom part 161 are sloped (e.g., an internal angle between the second side (e.g., top surface) for the bottom part 161 and an edge of the bottom part ranges between 95 degrees and 170 degrees). Similarly, optionally, a top side of the second part 162 of the multistep structure 160 has a larger lateral extent (e.g., is wider) than a second side (e.g., bottom side) of the second part 162 of the multistep structure 162, and thus the edges of the second part 162 are sloped (e.g., an internal angle between the top side of the second part 162 and an edge of the second part 162 ranges between 95 degrees and 170 degrees). In the aforementioned examples, the second side of the bottom part 161 is distal to the first side of the bottom part 161, and the top side of the second part 162 is distal to the second (bottom) side of the second part 162. Alternatively, in some of the first embodiments, the edge of the bottom part 161 and/or the second part 162 is vertical or substantially vertical (e.g., an internal angle between the second side (e.g., top surface) of the respective part 161 or 162 and an edge of the respective part ranges between 85 degrees and 95 degrees).

As shown in FIG. 1A2, in some of the first set of embodiments, both the bottom part 161 and second part 162 of resonator 100 extend from a position over the cavity 104 to a position over the substrate 103.

In some of the first set of embodiments, the materials of the multistep structure 160 include one or more of titanium, molybdenum, gold, tungsten, ruthenium, silicon, polysilicon, silicon oxide and silicon nitride. In some of the first set of embodiments, the materials of the multistep structure 160 are non-conductive materials, e.g., one or more of silicon, polysilicon, silicon oxide and silicon nitride. Using non-conductive materials for one or more of the frames or steps of the multistep structure improves the suppression or destructive interference of lateral acoustic waves in comparison with some other implementations of a BAW resonator with two or more frame layers or steps for destructive interference of lateral acoustic waves. More generally, in some embodiments, the materials of the multistep structure 160 include one or more metals, dielectrics and/or semiconductors. In some embodiments, two or more steps of parts of the multistep structure 160 comprise the same material or combination of materials, while in some other embodiments the bottom part 161 is formed from one material or combination of materials and the second part 162 is formed from a different material or combination of materials.

In some of the first set of embodiments, the bulk acoustic resonator includes a substrate, and a cavity (e.g., in the substrate) or mirror structure disposed under the stack, e.g., the cavity is disposed under the first electrode 120, and a portion of the first electrode 120 is positioned between the cavity 104 or mirror 108 and the bottom part 161 of the multistep structure 160. As discussed elsewhere in this document, in some embodiments, one or more additional layers (e.g., seed layer 150, and/or buffer 140) or materials are positioned between the cavity 104 (or mirror 108) and the first electrode 120.

In some of the first set of embodiments, the multistep structure includes two or more frame layers, each of which is formed during manufacture of the bulk acoustic resonator by depositing or removing material.

### Frame Layers on Opposite Sides of Piezoelectric Layer

Referring to FIG. 2A, in a second set of embodiments, a bulk acoustic wave (BAW) resonator 200 includes a stack of layers or structures, typically supported by a substrate 103. The stack 110 includes a piezoelectric layer 130 having a first side and an opposing second side; a first electrode 120 (sometimes called the bottom electrode) disposed under the first side of the piezoelectric layer 130; a second electrode 122 (sometimes call the top electrode) disposed over the second side of the piezoelectric layer; a first frame layer 201 having first dimensions disposed between the first electrode 120 and the piezoelectric layer 130 or disposed under underneath the first electrode 120, distal the piezoelectric layer 130; and a second frame layer 202 having second dimensions, different from the first dimensions, disposed over the second electrode 122 or between the piezoelectric layer 130 and the second electrode 122. In the second set of embodiments, the first frame layer 201 and second frame layer 202 are disposed on opposite sides of the piezoelectric layer 130, an active region of the stack 110 is configured to resonate in response to an electrical signal applied between the first electrode 120 and the second electrode 122, and the first frame layer 201 and the second frame layer 202 are arranged to provide destructive interference of lateral acoustic waves.

It is noted that in FIG. 2A, the first frame layer 201 is shown positioned between the first electrode 120 and the piezoelectric layer 130. In some embodiments, however, the first frame layer 201 is positioned below the first electrode 120, e.g., along a bottom portion of the first electrode 120.

Similarly, in FIG. 2A, the second frame layer 202 is shown positioned between the piezoelectric layer 130 and the second electrode 122. In some embodiments, however, as shown in FIG. 2C, the second frame layer 202 is positioned above (e.g., above and in contact with) the second electrode 122. As shown in FIG. 2B, in some of the second set of embodiments, the second frame layer 202 of resonator 200 extends from a position over the cavity 104 to a position over the substrate 103. Furthermore, in some of the second set of embodiments, the second frame layer 202 of resonator 200 is positioned above the second electrodes and also extends from a position over the cavity 104 to a position over the substrate 103.

In some of the second set of embodiments, the second frame layer 202 is thicker than the first frame layer 201. For example, the first frame layer 201 may have a thickness (e.g., height) between 100 angstroms (100 Å) and 2000 angstroms (2000 Å), while the second frame layer 202 has a thickness (e.g., height) between 200 angstroms (200 Å) and 4000 angstroms (4000 Å). However, in some embodiments, the second frame layer 202 has the same or substantially the same thickness as the first frame layer 201, within a predefined margin of error, for example, a margin of error of twenty percent, or ten percent. More generally, in some of the second set of embodiments, the thickness of the second frame layer 202 is equal or different from the thickness of the first frame layer 201. For example, the first frame layer 201 has a thickness (e.g., height) between 100 angstroms (100 Å) and 4000 angstroms (4000 Å), while the second frame layer 202 has a thickness (e.g., height) between 100 angstroms (100 Å) and 4000 angstroms (4000 Å).

In some of the second set of embodiments, the first frame layer has a larger lateral extent (e.g., is wider) than the second frame layer. For example, the first frame layer 201 may have a width between 0.5 microns (0.5 μm) and 6 microns (6 μm), while the second frame layer 202 has a width between 0.3 microns and 5 microns. The first frame layer 201 and second frame layer 202 having different lateral extents is important for providing destructive interference of lateral acoustic waves.

In some of the second set of embodiments, the first frame layer 201 includes a first side that is in contact with the first electrode 120 and a second side that is in contact with the piezoelectric layer 130, and the second frame layer 202 includes a first side that is in contact with the second electrode 122. Alternatively, in some of the second embodiments, only a first side of the first frame layer 201 is in contact with the first electrode 120, and the second frame layer 202 is not in contact with the second electrode 122 (e.g., the second frame layer 202 is separated from the second electrode 122 by another frame layer or other structure).

In some of the second set of embodiments, the first frame layer and/or the second frame layer has sloped edges, with a first side of a respective frame layer having a larger lateral extent than a second side of the respective frame layer (e.g., an internal angle between the second side (e.g., top surface) for the respective frame layer 201 or 202 and an edge of the respective frame layer ranges between 95 degrees and 170 degrees). Alternatively, in some of the second embodiments, the edge of the first frame layer 201 and/or the second frame 202 layer is vertical or substantially vertical (e.g., an internal angle between the second side (e.g., top surface) of the respective frame layer 201 or 202 and an edge of the respective fame layer ranges between 85 degrees and 95 degrees). In the aforementioned example, the second side of the respective frame layer 201 or 202 is distal to the first side of the respective frame layer.

In some of the second set of embodiments, the first frame layer 201 and second frame layer 202 are comprised of materials that include one or more of titanium, molybdenum, gold, tungsten, ruthenium, silicon, polysilicon, silicon oxide and silicon nitride. More generally, in some embodiments, the materials of the first frame layer 201 and second frame layer 202 include one or more metals, dielectrics and/or semiconductors. In some embodiments, two or more frame layers of the BAW resonator 200 comprise the same material or combination of materials, while in some other embodiments the first frame layer 201 is formed from one material or combination of materials and the second frame layer 202 is formed from a different material or combination of materials.

In some of the second set of embodiments, the first frame layer 201 and the first electrode 120, or a portion of the first electrode 120 in contact with the first frame layer 201, comprise a same material. Optionally, the first electrode 120 includes a stack of two or more materials. In some of the second set of embodiments, the first frame layer 201 is integrated in the first electrode 120. For example, the first electrode 120 includes an upper plane or surface, and the first frame layer 201 is disposed on the upper plane or surface of the first electrode 120. In some of the second set of embodiments, the first electrode 120 comprises a first material, and the first frame layer 201 is formed during manufacture by depositing an additional layer of the first material on top or underneath the first electrode 120, or by partially removing material of the first electrode 120. Alternatively, in some of the second embodiments, the first frame layer 201 comprises a different material than the first electrode 120.

In some of the second set of embodiments, the base structure 102 of the bulk acoustic resonator 200 includes a substrate 103 and a cavity 104 (e.g., in the substrate) or a mirror structure 108 (FIG. 1C) disposed under the stack 110. In some of the second set of embodiments, the stack 110 includes two or more frame layers, each of which is formed during manufacture of the bulk acoustic resonator by depositing or removing material.

### Base Structure with Cavity

In some embodiments, as shown in FIGS. 1A and 2, a cavity 104 is supported by and at least partially surrounded by the substrate 103. In such cases, the stack 110 is disposed over the cavity 104 and supported by the substrate 103. In some embodiments, the stack 110 is directly coupled to the substrate 103. In some embodiments, the first electrode 120 is directly coupled to the substrate 103, while in some other embodiments an optional seed layer 150 is disposed between the substrate and at least a portion of the first electrode.

In some embodiments, as shown in FIG. 1B, the BAW resonator 100 or 200 further includes a frame 106 (e.g., cavity frame) that is disposed over the substrate 103. The cavity 104 is supported by and is at least partially surrounded by the frame 106. In some embodiments, frame 106 is formed from or includes a material with high thermal conductivity (e.g., aluminum, gold, copper, silver, or diamond) and/or high electrical conductivity (e.g., aluminum, gold, copper, or silver). In some embodiments, the frame 106 is surrounded by a planarizing material 107, which forms a perimeter around the frame 106, so as to present a flat surface on which the stack 110 is to be formed and to ensure a high degree of structural integrity in the portion of the BAW resonator 100 or 200 that supports the stack suspended over the cavity 104. In some embodiments, planarizing material 107 is a dielectric material, such as polysilicon; in some embodiments, planarizing material 107 is the same as or similar to substrate 103 in composition. In embodiments in which the BAW resonator 100 or 200 includes a frame 106 , the stack 110 is disposed over the cavity 104 and supported by the frame 106. In some embodiments, the stack 110 is directly coupled to the frame 106. In some embodiments, the first electrode 120, which is a bottom layer of the stack 110, is directly coupled to the frame 106.

### Base Structure with Acoustic Reflector

In some embodiments, as shown in FIG. 1C, the cavity 104 in base structure 102 is replaced by an acoustic reflector 108, sometimes called an acoustic mirror. In such embodiments, the BAW resonator 100 or 200 includes the substrate 103, an acoustic reflector 108 arranged over the substrate 103, the piezoelectric layer 130, and the first and second electrodes 120, 122. The first electrode 120 is arranged between the acoustic reflector 108 and the piezoelectric layer 130, and the second electrode 122 is arranged along a portion of an upper surface of the piezoelectric layer 130. An area in which the piezoelectric layer 130 is arranged between overlapping portions of the first electrode 120 and the second electrode 122 is considered the active region of the resonator device 100. The acoustic reflector 108 is positioned between the substrate 103 and first electrode 120 (e.g., below the first electrode 120 and, if included in the BAW resonator 100 or 200, the seed layer 150), and reflects acoustic waves and thereby reduces or avoids their dissipation in the substrate 103. In some embodiments, the acoustic reflector 108 is a multilayer acoustic mirror that includes alternating layers of materials (e.g., SiOC, Si₃N₄, SiO₂, AlN, or Mo) of different acoustic impedances, optionally embodied in a Bragg mirror, deposited over the substrate 103. Inclusion of seed layer 150 in such BAW resonators is optional.

### Performance Comparisons

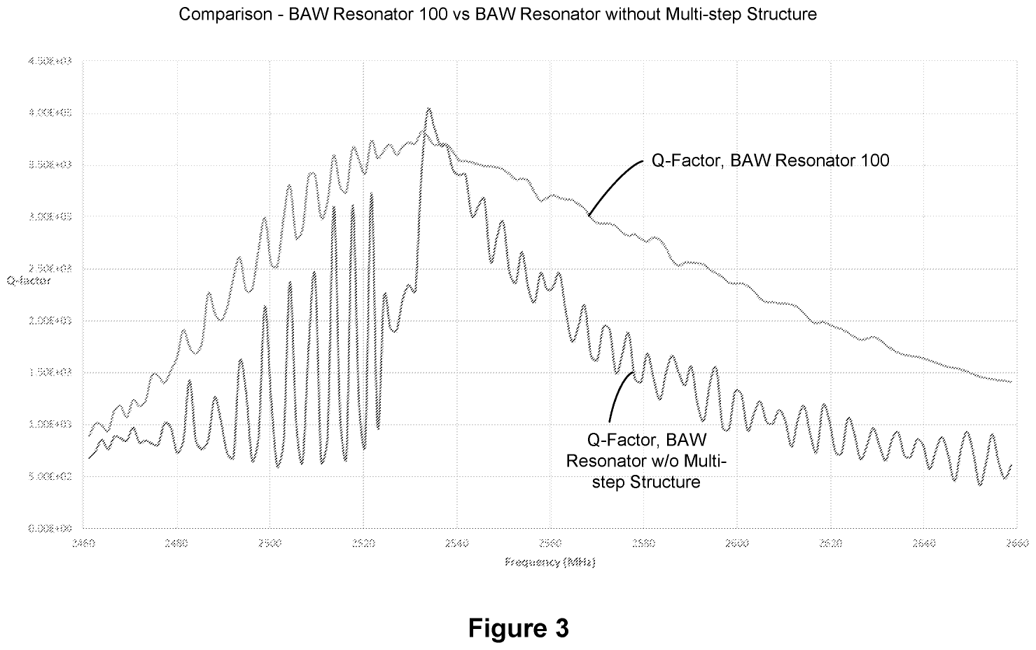

FIG. 3 is prophetic diagram comparing simulated performance (e.g., determined through the use of a circuit or device simulation program) of a bulk acoustic wave resonator 100 (FIG. 1A1) in accordance with the first set of embodiments with simulated performance of a hypothetical bulk acoustic wave resonator that does not include the multistep structure of the first set of embodiments (e.g., the resonator 100 of FIG. 1A1, but without the multistep structure 160). FIG. 3 shows a graph of the (computed) quality factor (also called the Q-factor) of both resonator 100 and the hypothetical bulk acoustic wave resonator, both having a resonance frequency (sometimes called a series resonance frequency) of about 2530 MHz (2.53 GHz). As shown, the quality factor for resonator 100 remains at a substantially higher level than the quality factor for the hypothetical bulk acoustic wave resonator over a wide range, from 70 MHz below the resonance frequency to more than 100 MHz above the resonance frequency, and has substantially smaller variation (e.g., smaller oscillations), within that interval, over essentially all frequency sub-ranges of 10 to 20 MHz. As a result, resonator 100 has substantially better performance (e.g., in filters, oscillators and synchronizers) than the hypothetical bulk acoustic wave resonator that does not include the multistep structure of the first set of embodiments. One aspect of the improved performance due to the structural improvements in resonator 100 is that the amount of energy lost in resonator 100 is substantially less the amount of energy that would be lost in the hypothetic resonator. Furthermore, due to the location of the multistep structure 160 above the piezoelectric layer 130 of the resonator 100, the quality of the piezoelectric layer 130 is not compromised by the addition of the multistep structure.

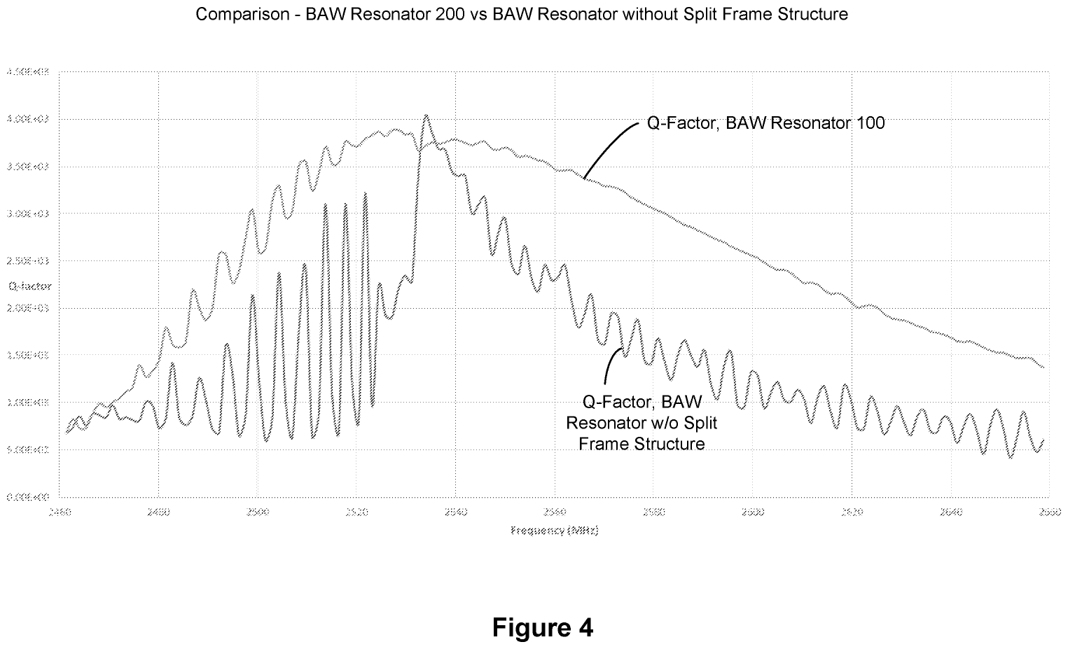

FIG. 4 is prophetic diagram comparing simulated performance of a bulk acoustic wave resonator 200 (FIG. 2A) in accordance with the second set of embodiments with simulated performance of a hypothetical bulk acoustic wave resonator that does not include the first and second frame layers of the second set of embodiments. FIG. 4 shows a graph of the (computed) quality factor (also called the Q-factor) of both resonator 200 and the hypothetical bulk acoustic wave resonator, both having a resonance frequency (sometimes called a series resonance frequency) of about 2530 MHz (2.53 GHz). As shown, the quality factor for resonator 200 remains at a substantially higher level than the quality factor for the hypothetical bulk acoustic wave resonator over a wide range, from 60 MHz below the resonance frequency to more than 100 MHz above the resonance frequency, and has substantially smaller variation (e.g., smaller oscillations), within that interval, over essentially all frequency sub-ranges of 10 to 20 MHz. As a result, resonator 200 has substantially better performance (e.g., in filters, oscillators and synchronizers) than the hypothetical bulk acoustic wave resonator that does not include the multistep structure of the first set of embodiments. One aspect of the improved performance due to the structural improvements in resonator 200 is that the amount of energy lost in resonator 200 is substantially less the amount of energy that would be lost in the hypothetic resonator. Furthermore, due to the location of the second frame layer 202 above the piezoelectric layer 130 of the resonator 200, and the use of a first frame layer 201 that can be integrated into the first (bottom) electrode, the quality of the piezoelectric layer 130 is not compromised by the addition of the first and second frame layers.

### Multilayer Buffer

As shown in FIGS. 1A1-1A2, in embodiments of resonator 100 (or resonator 200, FIG. 2A) that include a multilayer buffer 140, the multilayer buffer 140 includes two or more pairs of alternating layers, and each pair of the two or more pairs of alternating layers includes a layer of crystalline material having a first lattice constant and another layer of crystalline material having a lattice constant that is distinct (e.g., different) from the first lattice constant. For example, a first pair of the two or more pairs of alternating layers includes a first layer 144-1 and a second layer 144-2. The first layer 144-1 includes (e.g., is composed of) aluminum nitride (AlN), and the second layer 144-2 includes (e.g., is composed of) scandium aluminum nitride (ScₓAl₁₋ₓN).

In some embodiments, the concentration of Sc in the second layer 144-2 is between 0.5% and 30% such that the value of x is between 0.005 and 0.3 (e.g., 0.005≤x≤0.3). In some embodiments, the first layer 144-1 is disposed between the first electrode 120 and the second layer 144-2. In some embodiments, the second layer 144-2 is disposed over the first layer 144-1 and between the first layer 144-1 and the piezoelectric layer 130.

In some embodiments, the first layer 144-1 has a first thickness w1, and the second layer 144-2 has a second thickness w2. In some embodiments, the first thickness is equal to the second thickness (e.g., w1=w2). In some embodiments, the first thickness is different from the second thickness (e.g., w1≠w2). In some embodiments, each of the first layer 144-1 and the second layer 144-2 of the multilayer buffer 140 is between 10 to 1000 Angstroms in thickness (e.g., 10 Angstroms≤w1≤1000 Angstroms, and 10 Angstroms≤w2≤1000 Angstroms).

In some embodiments, the multilayer buffer 140 includes a second pair of the two or more pairs of alternating layers. The second pair of the two or more pairs of alternating layers includes a third layer 144-3 and a fourth layer 144-4. The third layer 144-3 includes (e.g., is composed of) a crystalline material having the first lattice constant, and the fourth layer 144-4 includes (e.g., is composed of) a crystalline material having a lattice constant that is different from the first lattice constant. In some embodiments, the third layer 144-3 includes aluminum nitride (AlN), and the fourth layer 144-4 includes scandium aluminum nitride (Scₓ′Al₁₋ₓ′N). In some embodiments, the third layer 144-3 is disposed between the second layer 144-2 and the fourth layer 144-2. In some embodiments, the fourth layer 144-4 is disposed over the third layer 144-3 and between the third layer 144-3 and the piezoelectric layer 130. In some embodiments, the fourth layer 144-4 is a top layer of the multilayer buffer 140, and the fourth layer 144-4 is adjacent to and coupled (e.g., directly coupled) to the piezoelectric material 130.

In some embodiments, the third layer 144-3 has the first thickness w1 (e.g., has a same thickness as the first layer 144-1), and the fourth layer 144-4 has the second thickness w2 (e.g., has a same thickness as the second layer 144-2).

In some embodiments, the second layer 144-2 and the fourth layer 144-4 both have a same second lattice constant that is different from the first lattice constant, and thus the second layer 144-2 and the fourth layer 144-4 have a same concentration of Sc (e.g., x=x′). In some embodiments, the fourth layer 144-4 has a lattice constant that is different from the second lattice constant of the second layer 144-2 such that a concentration of Sc in the fourth layer 144-4 is different from a concentration of Sc in the second layer 144-2 (e.g., x and x′have different values). In some embodiments, the concentration of Sc in the fourth layer 144-4 is higher than a concentration of Sc in the second layer 144-2 (e.g., x′>x). In some embodiments, the concentration of Sc in the fourth layer 144-4 is between 0.5% and 30% such that the value of x′is between 0.005 and 0.3 (e.g., 0.005≤x′≤0.3).

In some embodiments, the multilayer buffer 140 includes one or more additional pairs of alternating layers between the first pair of alternating layers and the second pair of alternating layers. Each additional pair of alternating layers includes a layer (sometimes herein called a fifth layer for ease of reference) of crystalline material having the first lattice constant and another layer (sometimes herein called a sixth layer for ease of reference) of crystalline material having a lattice constant that is different from the first lattice constant. In some embodiments, the sixth layer of crystalline material of each additional pair of alternating layers has the second lattice constant such that the sixth layer of crystalline material of each additional pair of alternating layers, the second layer 144-2 of crystalline material, and the fourth layer 144-4 of crystalline material have a same concentration of Sc. Alternatively, the sixth layer of crystalline material of each additional pair of alternating layers has a lattice constant that differs from the second lattice constant of the second layer 144-2 of crystalline material and differs from the lattice constant of the fourth layer 144-4 of crystalline material. For example, the sixth layer of crystalline material may have a concentration of Sc that is between x and x′. In some embodiments, the concentration of Sc in each pair of alternating layers increases monotonically with each successive layer such that the fourth layer 144-4 of crystalline material has a highest concentration of Sc relative to other layers of scandium aluminum nitride in the multilayer buffer 140. In some embodiments, the fifth layer of each additional pair of alternating layers has the first thickness w1 (e.g., has a same thickness as the first layer 144-1 and the third layer 144-3), and the sixth layer of each additional pair of alternating layers has the second thickness w2 (e.g., has a same thickness as the second layer 144-2 and the fourth layer 144-4).

It is to be understood that all references to a “same thickness” means thicknesses that are the same within a first predefined tolerance, where the first predefined tolerance, such as five percent (5%) or ten percent (10%), is generally twenty percent or less. Similarly, it is to be understood that all references to a same lattice constant or a same concentration of Sc means lattice constants, or concentrations, within a second predefined tolerance, where the second predefined tolerance, such as five percent (5%) or ten percent (10%), is generally ten percent or less.

In some embodiments, the two or more pairs of alternating layers in the multilayer buffer 140 (e.g., layers 144-1 through 144-4, and any additional layers) form a superlattice.

In some embodiments, each layer of the multilayer buffer 140 is between 10 to 1000 Angstroms in thickness.

In some embodiments, the multilayer buffer 140 also includes a base layer 142 of crystalline material that is disposed between the first electrode 120 and the first layer 144-1 of crystalline material. For example, the base layer 142 is adjacent to and coupled (e.g., directly coupled) to each of the first electrode 120 and the first layer 144-1 of crystalline material. The base layer 142 has a lattice constant that is different from the first lattice constant. In some embodiments, the base layer 142 has a lattice constant that is the same a lattice constant of the second layer 144-2 of crystalline material and the fourth layer 144-4 of crystalline material. In some embodiments, the base layer 142 includes (e.g., is composed of) scandium aluminum nitride (ScAlN).

The base layer 142 has a thickness w0. In some embodiments, the thickness w0 of the base layer 142 is the same as the thickness of the second layer 144-2 (e.g., w0=w2).

### Piezoelectric Layer

In some embodiments, piezoelectric layer 130 includes (e.g., is composed of) scandium aluminum nitride (Sc_{y}Al_{1-y}N). In some embodiments, the concentration of Sc in the piezoelectric layer 130 is between 0.5% and 30% such that the value of y is between 0.005 and 0.3. In some embodiments, the piezoelectric layer 130 has a concentration of Sc that is equal to or greater than the concentration of Sc in the fourth layer 144-4 of the multilayer buffer 140 (e.g., y>x′). In some embodiments, a high concentration of Sc (e.g., high composition of Sc) in the piezoelectric layer 130 allows the BAW resonator 100 to have a high coupling coefficient (Ksq). In general, the coupling coefficient (Ksq) of the BAW resonator 100 increases with increasing Sc concentration.

In some embodiments, such as when the piezoelectric layer 130 includes (e.g., is composed of) scandium aluminum nitride (Sc_{y}Al_{1-y}N) with a high concentration of Sc (e.g., high composition of Sc), inclusion of the multilayer buffer 140 between the first electrode 120 and the piezoelectric layer 130 improves the crystalline quality of the piezoelectric layer 130 compared to direct deposition of the piezoelectric layer 130 on the first electrode 120. Additionally, the inclusion of the multilayer buffer 140 allows good crystalline quality of straight, uniform, and high Sc concentration scandium aluminum nitride (Sc_{y}Al_{1-y}N) to be formed as the piezoelectric layer 130. Additionally, the inclusion of the multilayer buffer 140 results in a higher coupling coefficient (Ksq) for the BAW resonator 100 relative to BAW resonators that do not include a buffer layer or include a single layer buffer (e.g., a single layer of AlN) disposed between the first electrode 120 and the piezoelectric layer 130.

### Seed Layer

In some embodiments, as shown in FIGS. 1A1-1A2 and 1D, the stack 110 includes an optional seed layer 150 that is directly coupled to the substrate 103 such that the seed layer 150 is adjacent to the cavity 104 (or adjacent to an acoustic reflector 108, shown in FIG. 1C, in embodiments in which an acoustic reflector is used instead of cavity 104), and the first electrode 120 (e.g., the seed layer 150 is disposed between the cavity 104 (or acoustic reflector 108) and the first electrode 120).

In some embodiments, the stack 110 includes an optional seed layer 150 that is directly coupled to the frame 106 (FIG. 1B,) such that the seed layer 150 is adjacent to the cavity 104 and the first electrode 120 (e.g., the seed layer 150 is disposed between the cavity 104 and the first electrode 120).

In some embodiments, the seed layer 150 is a single layer of a crystalline material. For example, the seed layer 150 is a single layer of aluminum nitride (AlN). In another example, the seed layer 150 is a single layer of scandium aluminum nitride (ScⱼAl₁₋ⱼN).

In some embodiments, as shown in FIG. 1D, the seed layer 150 includes alternating sublayers of a crystalline material (e.g., a first crystalline material) having the first lattice constant and a crystalline material (e.g., a second crystalline material) having a lattice constant that is different from the first lattice constant. For example, the seed layer 150 includes a first sublayer 152-1 that includes (e.g., is composed of) aluminum nitride (AlN), and a second sublayer 152-2 that includes (e.g., is composed of) scandium aluminum nitride (ScⱼAl₁₋ⱼN). In some embodiments, the seed layer 150 also includes a third sublayer 152-3 that includes (e.g., is composed of) aluminum nitride (AlN), and a fourth sublayer 152-4 that includes (e.g., is composed of) scandium aluminum nitride (Sc_{j′}Al₁₋ⱼ′N). The third sublayer 152-3 is disposed between the second sublayer 152-2 and the fourth sublayer 152-4. In some embodiments, the fourth sublayer 152-4 has a same lattice constant as the second sublayer 152-2 such that the second sublayer 152-2 and the fourth sublayer 152-4 have a same concentration of Sc (e.g., j=j′). In some embodiments, the fourth sublayer 152-4 has a lattice constant that is different from the lattice constant of the second sublayer 152-2 such that a concentration of Sc in the fourth sublayer 152-4 is different from a concentration of Sc in the second sublayer 152-2(e.g., j≠j′). In some embodiments, the concentration of Sc in the fourth sublayer 152-4 is higher than a concentration of Sc in the second sublayer 152-2 (e.g., j<j′). In some embodiments, the concentration of Sc in the second sublayer 152-2 is between 0.5% and 30% such that the value of j is between 0.005 and 0.3 (e.g., 0.005≤j≤0.3). In some embodiments, the concentration of Sc in the fourth sublayer 152-4 is between 0.5% and 30% such that the value of j′is between 0.005 and 0.3 (e.g., 0.005≤j′≤0.3).

In another example, the first sublayer 152-1 of the seed layer 150 includes (e.g., is composed of) scandium aluminum nitride (ScⱼAl₁₋ⱼN), and the second sublayer 152-2 includes (e.g., is composed of) aluminum nitride (AlN). In some embodiments, the seed layer 150 also includes a third sublayer 152-3 that includes (e.g., is composed of) scandium aluminum nitride (Sc_{j′}Al₁₋ⱼ′N), and a fourth sublayer 152-4 that includes (e.g., is composed of) aluminum nitride (AlN). The third sublayer 152-3 is disposed between the second sublayer 152-2 and the fourth sublayer 152-4. In some embodiments, the third sublayer 152-3 has a same lattice constant as the first sublayer 152-1 such that the first sublayer 152-1 and the third sublayer 152-3 have a same concentration of Sc (e.g., j=j′). In some embodiments, the third sublayer 152-3 has a lattice constant that is different from the lattice constant of the first sublayer 152-1 such that a concentration of Sc in the third sublayer 152-3 is different from a concentration of Sc in the first sublayer 152-1 (e.g., j≠j′). In some embodiments, the concentration of Sc in the third sublayer 152-3 is higher than a concentration of Sc in the first sublayer 152-1 (e.g., j<j′). In some embodiments, the concentration of Sc in the first sublayer 152-1 is between 0.5% and 30% such that the value of j is between 0.005 and 0.3 (e.g., 0.005≤j≤0.3). In some embodiments, the concentration of Sc in the third sublayer 152-3 is between 0.5% and 30% such that the value of j′is between 0.005 and 0.3 (e.g., 0.005≤j′≤0.3).

In some embodiments, the concentration of Sc in the seed layer, or in each sublayer of the seed layer that includes Sc, is between 0.5% and 30% (e.g., 0.005≤j, j′≤0.3).

In some embodiments, the first sublayer 152-1 of the seed layer 150 is a bottom of the seed layer 150 that is adjacent to the cavity 104 (or acoustic reflector 108, FIG. 1C).

In some embodiments, the fourth sublayer 152-4 of the seed layer 150 is a top of the seed layer 150 and is adjacent to and coupled to the first electrode 120.

In some embodiments, the first sublayer 152-1 of the seed layer 150 has a third thickness w3, and the second sublayer 152-2 of the seed layer 150 has a fourth thickness w4. In some embodiments, the third thickness is equal to the fourth thickness (e.g., w3=w4). In some embodiments, the third thickness is different from the fourth thickness (e.g., w3≠w4).

In some embodiments, the third sublayer 152-3 of the seed layer 150 has the third thickness w3 (e.g., has a same thickness as the first sublayer 152-1), and the fourth sublayer 152-4 has the fourth thickness w4 (e.g., has a same thickness as the second sublayer 152-2).

In some embodiments, the seed layer 150 includes additional alternating sublayers between the second sublayer 152-2 and the third sublayer 152-3, such as one or more additional pairs of sublayers, each pair including a sublayer that includes (e.g., is composed of) aluminum nitride (AlN) and another sublayer that includes (e.g., is composed of) scandium aluminum nitride (ScAlN).

In some embodiments, each sublayer of the seed layer 150 that includes the scandium aluminum nitride (ScAlN) has a same concentration of Sc. In some embodiments, the concentration of Sc in sublayers of the seed layer 150 that include scandium aluminum nitride (ScAlN) increases monotonically with each successive layer such that the fourth sublayer 152-4 of the seed layer 150 has a highest concentration of Sc relative to other layers of scandium aluminum nitride in the seed layer 150. In some embodiments, other arrangements of Sc concentrations are present in sublayers of the seed layer 150. For example, a sublayer of the seed layer 150 that includes scandium aluminum nitride (ScAlN) may have a concentration of Sc that is the same as or different from another sublayer of the seed layer 150 that includes the scandium aluminum nitride (ScAlN).

In some embodiments, the seed layer 150 includes as few as one sublayer (e.g., a single layer seed layer 150). In some embodiments, the seed layer 150 includes a plurality of sublayers. In some embodiments, the seed layer 150 includes as many as 99 sublayers.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A bulk acoustic resonator, comprising:
a stack that includes:
a piezoelectric layer having a first side and an opposing second side;
a first electrode disposed under the first side of the piezoelectric layer;
a second electrode disposed over the second side of the piezoelectric layer; and
a multistep structure with a bottom part having first dimensions disposed between the piezoelectric layer and second electrode and a second part having second dimensions, different from the first dimensions, disposed between the bottom part of the multistep structure and the second electrode;
wherein an active region of the stack is configured to resonate in response to an electrical signal applied between the first electrode and the second electrode; and
wherein the multistep structure is arranged to provide destructive interference of lateral acoustic waves.

2. The bulk acoustic resonator of claim 1, wherein the bottom part of the multistep structure has a same thickness as the second part of the multistep structure within a predefined margin of error.

3. The bulk acoustic resonator of claim 1, wherein the bottom part of the multistep structure is wider than the second part of the multistep structure.

4. The bulk acoustic resonator of claim 1, wherein the bottom part of the multistep structure includes a first side that is in contact with the piezoelectric layer, and the second part of the multistep structure includes a first side that is in contact with a second side of the bottom part of the multistep structure.

5. The bulk acoustic resonator of claim 4, wherein the first side of the bottom part of the multistep structure has a larger lateral extent than the second side of the bottom part of the multistep structure.

6. The bulk acoustic resonator of claim 1, wherein the materials of the multistep structure include one or more of titanium, molybdenum, gold, tungsten, ruthenium, silicon, polysilicon, silicon oxide and silicon nitride.

7. The bulk acoustic resonator of claim 1, further including a cavity or a mirror disposed under the first electrode, wherein a portion of the first electrode is positioned between the cavity or mirror and the bottom part of the multistep structure.

8. The bulk acoustic resonator of claim 1, further including a cavity or a mirror disposed under the stack.

9. The bulk acoustic resonator of claim 1, wherein the multistep structure includes two or more frame layers, each of which is formed during manufacture of the bulk acoustic resonator by depositing or removing material.

10. A bulk acoustic resonator, comprising:
a stack that includes:
a piezoelectric layer having a first side and an opposing second side;
a first electrode disposed under the first side of the piezoelectric layer;
a second electrode disposed over the second side of the piezoelectric layer;
a first frame layer having first dimensions disposed between the first electrode and the piezoelectric layer or disposed under the first electrode, distal the piezoelectric layer; and
a second frame layer having second dimensions, different from the first dimensions, disposed over the second electrode or between the piezoelectric layer and the second electrode;
wherein
the first frame layer and second frame layer are disposed on opposite sides of the piezoelectric layer;
an active region of the stack is configured to resonate in response to an electrical signal applied between the first electrode and the second electrode; and
the first frame layer and the second frame layer are arranged to provide destructive interference of lateral acoustic waves.

11. The bulk acoustic resonator of claim 10, wherein the second frame layer has a same thickness as the first frame layer within a predefined margin of error.

12. The bulk acoustic resonator of claim 11, wherein the first frame layer has a larger lateral extent than the second frame layer.

13. The bulk acoustic resonator of claim 10, wherein the first frame layer includes a first side that is in contact with the first electrode and a second side that is in contact with the piezoelectric layer, and the second frame layer includes a first side that is in contact with the second electrode.

14. The bulk acoustic resonator of claim 10, wherein a first side of the first frame layer has a larger lateral extent than a second side of the first frame layer.

15. The bulk acoustic resonator of claim 10, wherein the materials of the first and second frame layers include one or more of titanium, molybdenum, gold, tungsten, ruthenium, silicon, polysilicon, silicon oxide and silicon nitride.

16. The bulk acoustic resonator of claim 10, wherein the first frame layer and the first electrode, or a portion of the first electrode in contact with the first frame layer, comprise a same material.

17. The bulk acoustic resonator of claim 16, wherein the first frame layer is integrated in the first electrode.

18. The bulk acoustic resonator of claim 10, wherein the first electrode comprises a first material, and first frame layer is formed during manufacture by depositing an additional layer on top or underneath the first electrode, or by partially removing material of the first electrode.

19. The bulk acoustic resonator of claim 10, further including a cavity or a mirror disposed under the first electrode, wherein a portion of the first electrode is positioned between the cavity or mirror and the first frame layer and the second frame layer.

20. The bulk acoustic resonator of claim 10, including a cavity or a mirror disposed under the stack.

21. A bulk acoustic resonator, comprising:
a stack that includes:
a piezoelectric layer having a first side and an opposing second side;
a first electrode disposed under the first side of the piezoelectric layer;
a second electrode disposed over the second side of the piezoelectric layer;
a first frame layer having first dimensions disposed between the first electrode and the piezoelectric layer; and
a second frame layer having second dimensions, different from the first dimensions, disposed between the piezoelectric layer and the second electrode;
wherein
the first frame layer and second frame layer are disposed on opposite sides of the piezoelectric layer;
an active region of the stack is configured to resonate in response to an electrical signal applied between the first electrode and the second electrode; and
the first frame layer and the second frame layer are arranged to provide destructive interference of lateral acoustic waves.

22. A bulk acoustic resonator, comprising:
a stack that includes:
a piezoelectric layer having a first side and an opposing second side;
a first electrode disposed under the first side of the piezoelectric layer;
a second electrode disposed over the second side of the piezoelectric layer;
a first frame layer having first dimensions disposed between the first electrode and the piezoelectric layer; and
a second frame layer having second dimensions, different from the first dimensions, disposed over the second electrode;
wherein
the first frame layer and second frame layer are disposed on opposite sides of the piezoelectric layer;
an active region of the stack is configured to resonate in response to an electrical signal applied between the first electrode and the second electrode; and
the first frame layer and the second frame layer are arranged to provide destructive interference of lateral acoustic waves.
